(19) United States
(12) Patent Application Publication
(10) Pub. No.: US 2005/0079297 A1
(43) Pub. Date: Apr. 14, 2005

(54) Method for forming inorganic oriented film, inorganic oriented film, substrate for electronic device, liquid crystal panel, and electronic device

(76) Inventors: Hidenobu Ota, Suwa-shi (JP); Yukihiro Endo, Suwa-shi (JP)

Correspondence Address: HARNESS, DICKEY & PIERCE, P.L.C., P.O. BOX 828, BLOOMFIELD HILLS, MI, 48303, US

(21) Appl. No.: 10/931,804

(22) Filed: Sep. 1, 2004

(30) Foreign Application Priority Data
Sep. 4, 2003 (JP) 2003-313315

(51) Int. Cl. C23C 14/32; B32B 1/00

(52) U.S. Cl. 428/1.32; 204/192.26; 204/192.23; 428/1.2

(57) ABSTRACT

A method for forming an inorganic oriented film is provided for forming an inorganic oriented film on a base material by a magnetron sputtering method. The method comprises the steps of reducing the pressure of an atmosphere in the vicinity of the base material to 5.0×10⁻² Pa or below, causing a plasma to collide with a target provided opposite the base material, drawing out the sputtered particles, irradiating the base material with the sputtered particles with an inclination at a prescribed angle, θs, with respect to the direction perpendicular to the surface of the base material where the inorganic oriented film will be formed, and forming an inorganic oriented film composed substantially of an inorganic material on the base material. The prescribed angle θs is preferably 60° or more. The distance between the base material and the target is preferably 150 mm or more.

### RELATED APPLICATIONS

This application claims priority to Japanese Patent Application No. 2003-313315 filed Sep. 4, 2003 which is hereby expressly incorporated by reference herein in its entirety.

### BACKGROUND

1. Technical Field

The present invention relates to a method for forming an inorganic oriented film, an inorganic oriented film, a substrate for an electronic device, a liquid crystal panel, and an electronic device.

2. Background

Projection display devices for projecting images on a screen are known. Liquid crystal panels have been mainly used for forming images in such projection display devices.

Such liquid crystal panels usually have an oriented film set so that a prescribed pretilt angle is demonstrated in order to orient liquid crystal molecules in a fixed direction. A method for the manufacture of such oriented films is known by which a thin film composed of a polymer compound such as a polyimide, which was formed on a substrate, is unidirectionally rubbed with a cloth such as rayon (for example, see JP-A-H10-161133 (claims)).

However, the oriented films composed of polymer compounds such as polyimides sometimes demonstrate light-induced deterioration under certain working environments and durations of use. If such light-induced deterioration occurs, materials constituting the oriented film, liquid crystal layer, and the like can decompose and the decomposition products can produce an adverse effect on the performance of liquid crystals.

Another problem is that the rubbing treatment produces electrostatic charges and dust, thereby decreasing reliability.

It is an object of the present invention to provide an inorganic oriented film that has excellent light resistance and allows for a more reliable control of a pretilt angle, to provide a substrate for an electronic device, a liquid crystal panel, and an electronic device comprising such an inorganic oriented film, and to provide a method for forming such an inorganic oriented film.

### SUMMARY

The above-described object is attained by the following invention.

The method for forming an inorganic oriented film in accordance with the present invention is a method for forming an inorganic oriented film on a base material by a magnetron sputtering method, comprising the steps of: reducing the pressure of an atmosphere in the vicinity of the base material to 5.0×10⁻² Pa or below, causing plasma to collide with a target provided opposite the base material, and drawing out the sputtered particles; irradiating the base material with the sputtered particles from the direction inclined at a prescribed angle θs with respect to the direction perpendicular to the surface of the base material where the inorganic oriented film will be formed; and forming the inorganic oriented film composed substantially of an inorganic material on the substrate.

As a result, an inorganic oriented film that has excellent light resistance and allows for a more reliable control of the pretilt angle can be obtained.

In the method for forming an inorganic oriented film in accordance with the present invention, the prescribed angle θs is preferably 60° or more.

In this case, an inorganic oriented film in which columnar crystals are arranged with an inclination can be obtained more advantageously. As a result, the obtained inorganic oriented film will have a better function of controlling the orientation state of liquid crystal molecules.

In the method for forming an inorganic oriented film in accordance with the present invention, the distance between the base material and the target is preferably 150 mm or more.

In this case, an inorganic oriented film in which columnar crystals are arranged with an inclination can be obtained more advantageously. Furthermore, the inorganic oriented film thus formed can be effectively prevented from damage by the generated plasma.

In the method for forming an inorganic oriented film in accordance with the present invention, when the inorganic oriented film is formed, a maximum magnetic flux density on the surface of the target with which the plasma collides, in the direction parallel to the surface of the target, is preferably 1000 G or higher.

In this case, plasma can be generated with good efficiency. As a result, the rate of forming the inorganic oriented film can be increased.

In the method for forming an inorganic oriented film in accordance with the present invention, the inorganic material is preferably capable of columnar crystallization.

In this case, the control of the orientation state (pretilt angle) of liquid crystal molecules (when no voltage is applied) constituting the liquid crystal layer is facilitated.

In the method for forming an inorganic oriented film in accordance with the present invention, the inorganic material preferably comprises an oxide of silicon as the main component.

In this case, the obtained liquid crystal panel will have enhanced light resistance.

The inorganic oriented film in accordance with the present invention is formed by the method for forming an inorganic oriented film in accordance with the present invention.

In this case, an inorganic oriented film that has excellent light resistance and allows for a more reliable control of the pretilt angle can be provided.

In the inorganic oriented film in accordance with the present invention, the columnar crystals are preferably arranged with an inclination at the prescribed angle to the base material.

In this case, a pretilt angle can be demonstrated and the orientation state of liquid crystal molecules can be controlled more advantageously.

In the inorganic oriented film in accordance with the present invention, the average thickness of the inorganic oriented film is 0.02-0.3 μm.

As a result, a more suitable pretilt angle can be achieved so that the orientation state of liquid crystal molecules can be controlled more advantageously.

A substrate for an electronic device in accordance with the present invention comprises electrodes and the inorganic oriented film in accordance with the present invention provided on the substrate.

In this case, a substrate for an electronic device with excellent light resistance can be provided.

A liquid crystal panel in accordance with the present invention comprises the inorganic oriented film in accordance with the present invention and a liquid crystal layer.

In this case, a liquid crystal panel with excellent light resistance can be provided.

The liquid crystal panel in accordance with the present invention comprises a pair of the inorganic oriented films in accordance with the present invention and also comprises a liquid crystal layer between the pair of inorganic oriented films.

In this case, a liquid crystal panel with excellent light resistance can be provided.

An electronic device in accordance with the present invention comprises the liquid crystal panel in accordance with the present invention.

In this case, a highly reliable electronic device can be provided.

The electronic device in accordance with the present invention has a light valve comprising the liquid crystal panel in accordance with the present invention and projects images by using at least one such light valve.

In this case, a highly reliable electronic device can be provided.

An electronic device in accordance with the present invention comprises three light valves corresponding to red color, green color, and blue color for forming images, a light source, a color separation optical system for separating the light from the light source into red, green, and blue lights, and guiding each such light into the corresponding light valve, a color synthesizing optical system for synthesizing each image, and a projecting optical system for projecting the synthesized image, wherein the light valve comprises the liquid crystal panel in accordance with the present invention.

The present invention can provide an inorganic oriented film that has excellent light resistance and allows for a more reliable control of a pretilt angle, a substrate for an electronic device, a liquid crystal panel, and an electronic device comprising such an inorganic oriented film, and a method for forming such an inorganic oriented film.

### BRIEF DESCRIPTION OF THE DRAWINGS

FIG. 1 is a schematic longitudinal sectional view illustrating a first embodiment of the liquid crystal panel in accordance with the present invention.

FIG. 2 is a longitudinal sectional view illustrating an inorganic oriented film formed by the method in accordance with the present invention.

FIG. 3 is a schematic diagram of a sputtering apparatus used in the method for forming an inorganic oriented film in accordance with the present invention.

FIG. 4 is a schematic longitudinal sectional view illustrating a second embodiment of the liquid crystal panel in accordance with the present invention.

FIG. 5 is a perspective view illustrating the configuration of a mobile (or notebook) personal computer employing the electronic device in accordance with the present invention.

FIG. 6 is a perspective view illustrating the configuration of a cellular phone (including a Personal Handyphone System (PHS)) employing the electronic device in accordance with the present invention.

FIG. 7 is a perspective view illustrating the configuration of a digital still camera employing the electronic device in accordance with the present invention.

FIG. 8 illustrates schematically the optical system of the projection display device employing the electronic device in accordance with the present invention.

### DETAILED DESCRIPTION

The method for forming an inorganic oriented film, substrate for an electronic device, a liquid crystal panel, and an electronic device in accordance with the present invention will be described below in greater detail with reference to the appended drawings.

Prior to explaining the method for forming an inorganic oriented film, the liquid crystal panel in accordance with the present invention will be explained.

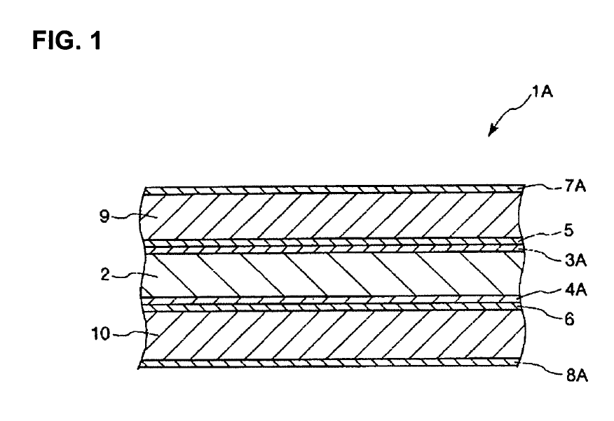

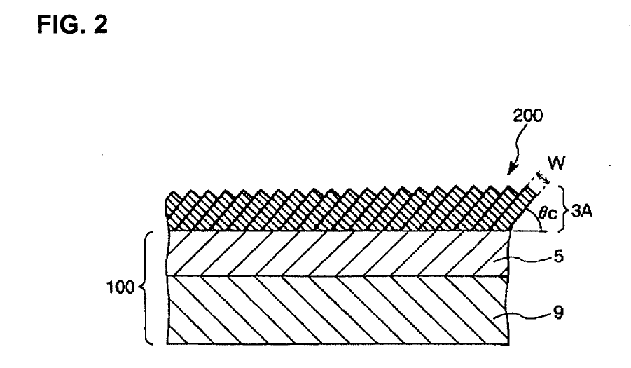

FIG. 1 is a schematic longitudinal sectional view illustrating a first embodiment of the liquid crystal panel in accordance with the present invention. FIG. 2 is a longitudinal sectional view illustrating an inorganic oriented film formed by the method in accordance with the present invention. As shown in FIG. 1, a liquid crystal panel 1A comprises a liquid crystal layer 2, inorganic oriented films 3A, 4A, transparent electrically conductive films 5, 6, polarizing films 7A, 8B, and substrates 9, 10.

The liquid crystal layer 2 is composed substantially of liquid crystal molecules. Any liquid crystal liquid molecules capable of orientation, such as nematic liquid crystals and smectic liquid crystals, may be used as liquid crystal molecules constituting the liquid crystal layer 2. In case of a TN-type liquid crystal panel, it is preferred that nematic liquid crystals be formed, examples thereof including phenylcyclohexane derivative liquid crystals, biphenyl derivative liquid crystals, biphenylcyclohexane derivative liquid crystals, terphenyl derivative liquid crystals, phenylether derivative liquid crystals, phenylester derivative liquid crystals, bicyclohexane derivative liquid crystals, azomethine derivative liquid crystals, azoxy derivative liquid crystals, pyrimidine derivative liquid crystals, dioxane derivative liquid crystals, and cubane derivative liquid crystals. Those nematic liquid crystal molecules also include liquid crystal molecules obtained by introducing a fluorine-containing substituent such as a monofluoro group, difluoro group, trifluoro group, trifluoromethyl group, trifluoromethoxy group, and difluoromethoxy group.

Inorganic oriented films 3A, 4A are disposed on both surfaces of the liquid crystal layer 2.

Further, the inorganic oriented film 3A is formed on a base material 100 composed of the below-described transparent electrically conductive film 5 and substrate 9, and the inorganic oriented film 4A is formed on a base material 101 composed of the below-described transparent electrically conductive film 6 and substrate 10.

The inorganic oriented films 3A, 4A have a function of controlling the orientation state (when no voltage is applied) of liquid crystal molecules constituting the liquid crystal layer 2.

Such inorganic oriented films 3A, 4A can be formed, for example, by the below-described method (method for forming an inorganic oriented film in accordance with the present invention). In those inorganic oriented films, as shown in FIG. 2, columnar crystals are arranged with an inclination at a prescribed angle, θc, in the prescribed (fixed) direction with respect to a surface direction of the surface of the base material 100 where the inorganic oriented film has been formed. With such a configuration, a pretilt angle can be demonstrated and the orientation state of liquid crystal molecules can be controlled more advantageously.

The inclination angle, θc, of columnar crystals with respect to the base material 100 is preferably 30-60°, more preferably 40-50°. In this case, a more appropriate pretilt angle can be demonstrated and the orientation state of liquid crystal molecules can be controlled more advantageously.

Further, the width, W, of such columnar crystals is preferably 10-40 nm, more preferably 10-20 nm. In this case, a more appropriate pretilt angle can be demonstrated and the orientation state of liquid crystal molecules can be controlled more advantageously.

The inorganic oriented films 3A, 4A are composed substantially of an inorganic material. Because inorganic materials generally have chemical stability superior to that of organic materials, they have an especially good light resistance by comparison with the conventional oriented films composed of organic materials.

The inorganic material constituting the inorganic oriented films 3A, 4A is preferably capable of columnar crystallization, as shown in FIG. 2. As a result, the control of the orientation state (pretilt angle) of the liquid-crystal molecules (when no voltage is applied) constituting the liquid crystal layer 2 can be facilitated.

For example, silicon oxides such as SiO₂ and SiO and metal oxides such as MgO and ITO can be used as the aforementioned inorganic materials. Among them, it is especially preferred that a silicon oxide be used. As a result, the obtained liquid crystal panel will have better light resistance.

The inorganic oriented films 3A, 4A preferably have an average thickness of 0.02-0.3 μm, more preferably 0.02-0.1 μm. If the average thickness is less than the aforementioned lower limit value, it is sometimes difficult to obtain a sufficiently uniform pretilt angle in all the locations. On the other hand, if the average thickness exceeds the aforementioned upper limit value, the drive voltage can rise and power consumption can increase.

The transparent electrically conductive film 5 is disposed on the outer surface side (the surface on the opposite side from the surface that faces the liquid crystal layer 2) of the inorganic oriented film 3A. Similarly, the transparent electrically conductive film 6 is disposed on the outer surface side (the surface on the opposite side from the surface that faces the liquid crystal layer 2) of the inorganic oriented film 4A.

The transparent electrically conductive films 5, 6 have a function of driving (changing the orientation) the liquid crystal molecules of the liquid crystal layer 2 by providing conductivity therebetween.

Control of the conductivity between the transparent electrically conductive films 5, 6 is carried out by controlling the electric current supplied from a control circuit (not shown in the figures) connected to the transparent electrically conductive films.

The transparent electrically conductive films 5, 6 have electric conductivity and are composed, for example, of indium tin oxide (ITO), indium oxide (IO), or tin oxide (SnO₂).

The substrate 9 is disposed on the outer surface side (the surface on the opposite side from the surface that faces the inorganic oriented film 3A) of the transparent electrically conductive film 5. Similarly, the substrate 10 is disposed on the outer surface side (the surface on the opposite side from the surface that faces the inorganic oriented film 4A) of the transparent electrically conductive film 6.

The substrates 9, 10 have a function of supporting the above-described liquid crystal layer 2, inorganic oriented films 3A, 4A, transparent electrically conductive films 5, and 6, and the below described polarizing films 7A, 8A. No specific limitation is placed on the materials constituting the substrates 9, 10. Examples of suitable materials include glass such as quartz glass and plastic materials such as polyethylene terephthalate. Among them, glass such as quartz glass is especially preferred. In this case, it is possible to obtain a liquid crystal panel with better stability and high resistance to deflection. The description of sealing materials, wiring, and the like with reference to FIG. 1 is omitted.

The polarizing film 7A (polarizing plate) is disposed on the outer surface side (the surface on the opposite side from the surface that faces the transparent electrically conductive film 5) of the substrate 9. Similarly, polarizing film 8A (polarizing plate) is disposed on the outer surface side (the surface on the opposite side from the surface that faces the transparent electrically conductive film 6) of the substrate 10.

Polyvinyl alcohol (PVA) is an example of material constituting the polarizing films 7A, 8A. A material obtained by doping the aforementioned material with iodine may be also used for the polarizing film.

For example, a film composed of the aforementioned material and subjected to uniaxial stretching can be used as the polarizing film.

Disposing such polarizing films 7A, 8A makes it possible to conduct more reliable control of light transmittance by adjusting the degree of conductivity.

The directions of the polarization axes of the polarizing films 7A, 8A are usually set according to the orientation directions of the inorganic oriented films 3A, 4A.

A method for forming an inorganic oriented film in accordance with the present invention will be described below.

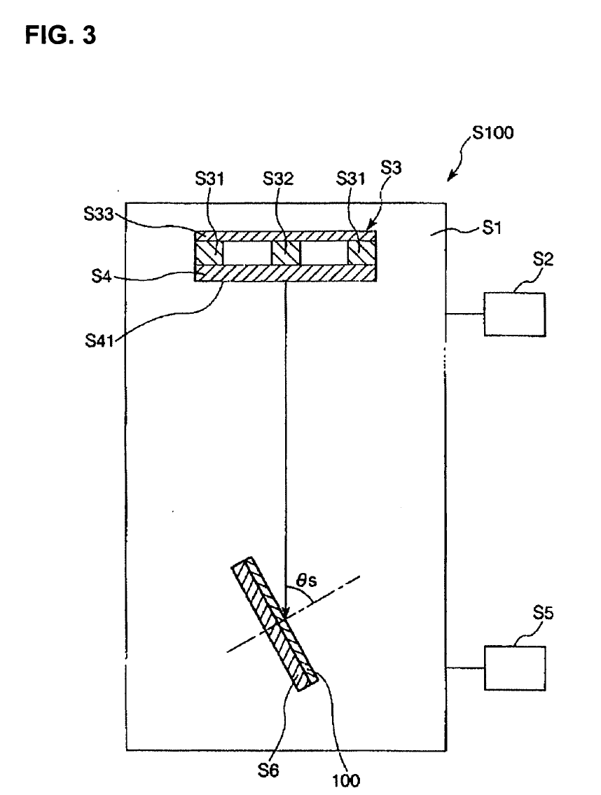

FIG. 3 is a schematic drawing of a sputtering apparatus used in the method for forming an inorganic oriented film in accordance with the present invention.

In the present embodiment, the explanation will be conducted based on using the sputtering apparatus of the configuration shown in the figure.

A sputtering apparatus S100 shown in FIG. 3 comprises a vacuum chamber S1, a gas supply source S2 for supplying a gas into the vacuum chamber S1, an electrode S3 for generating plasma by electric discharge, a target S4 for generating sputtered particles by plasma collision, an evacuation pump S5 for controlling the pressure inside the vacuum chamber S1, and a base material holder S6 for fixing a base material for forming an inorganic oriented film inside the vacuum chamber S1.

The electrode S3 is a magnetron cathode and comprises a pair of magnets S31, S32 installed behind (on the side opposite to the surface with which plasma collides) the target S4 and a yoke S33 fastening the pair of magnets S31, S32. The electrode S3 is connected to a power source for electric discharge (not shown in the figure).

The pair of magnets S31, S32 are permanent magnets for forming a leakage magnetic field in front (side of the surface with which plasma collides) of the target S4. The magnet S31 is a ring-shaped magnet (for example, S pole), and the magnet S32 is a cylindrical magnet (for example, N pole). The magnet S31 is so disposed as to surround the magnet S32 with a gap therebetween.

When the sputtering apparatus with the configuration shown in the figure is used, the inorganic oriented film is formed in the following manner. A representative case of forming the inorganic oriented film 3A is explained below.

1. The base material 100 is disposed on the base material holder S6 inside the vacuum chamber S1.

2. The vacuum chamber S1 is evacuated with the evacuation pump S5.

3. A gas is supplied from the gas supply source S2 into the vacuum chamber S1.

4. A voltage (discharge voltage) is applied to the electrode S3 from a power source for discharge (not shown in the figure).

5. If a high frequency is applied to the electrode S3, the gas is ionized and plasma is generated.

6. The generated plasma collides with the target S4 and sputtered particles are drawn out.

7. The drawn-out sputtered particles are emitted mainly toward the base material 100 from the direction inclined at the prescribed angle, θs, to the direction perpendicular to the surface of the base material 100 where the inorganic oriented film 3A will be formed, and a substrate (substrate for an electronic device (substrate 200 for an electronic device) in accordance with the present invention) in which the inorganic oriented film 3A is formed on the base material 100 is obtained.

The base material holder S6 is moved or rotated in advance so that the sputtered particles generated from the target S4 are emitted with an inclination at the prescribed angle (irradiation angle), θs, to the direction perpendicular to the surface of the base material 100 where the inorganic oriented film 3A will be formed, but it may be also moved or rotated so that the irradiation angle becomes θs, while irradiating the sputtered particles.

With the method for forming an inorganic oriented film in accordance with the present invention, sputtered particles are emitted onto the base material with an inclination at the prescribed angle to the direction perpendicular to the surface of the base material where the inorganic oriented film will be formed, after the pressure of the atmosphere in the vicinity of the base material was reduced to 5.0×10⁻² Pa or below. As a result, an inorganic oriented film that excels in light resistance and allows for more reliable control of the pretilt angle can be obtained. In particular, selecting appropriate materials, etc., makes it possible to form with a higher efficiency an inorganic oriented film composed of columnar crystals inclined to the prescribed (fixed) direction on the base material. Such an effect can be obtained when the above-described conditions are satisfied simultaneously.

By contrast, for example, when the usual sputtering method or vapor deposition method is used, a film capable of functioning as an oriented film cannot be obtained.

Further, when the pressure of the atmosphere in the vicinity of the base material is higher than 5.0×10⁻² Pa, the ability of emitted sputtered particles to move along a straight line is degraded. As a result, sufficient orientation of the surface of the obtained inorganic oriented film cannot be obtained.

When the sputtered particles are emitted without an inclination to the direction perpendicular to the surface of the base material where the inorganic oriented film will be formed, a film capable of functioning as an oriented film cannot be obtained.

The irradiation angle, θs, of the sputtered particles is preferably 60° or more, more preferably 70-85°, and even more preferably 75-85°. As a result, an inorganic oriented film in which columnar crystals are arranged in an inclined state can be formed more advantageously. As a result, the inorganic oriented film obtained has a better function of controlling the orientation state of liquid crystal molecules. By contrast, if the irradiation angle, θs, is too small, a sufficient pretilt angle cannot be obtained and there is a possibility that a sufficient function of controlling the orientation state of liquid crystal molecules will not be obtained. On the other hand, if the irradiation angle, θs, is too large, a problem of decreased production efficiency can arise.

No specific limitation is placed on the gas supplied form the gas supply source S2 into the vacuum chamber S1, provided that it is a rare gas. Among such gases, argon is especially preferred. With such a gas, the formation rate (sputtering rate) of the inorganic oriented film 3A can be increased.

The temperature of the base material 100 is preferably comparatively low when the inorganic oriented film 3A is formed. More specifically, the temperature of the base material 100 is preferably 200° C. or below, more preferably 100° C. or below, even more preferably 25-40° C. As a result, the migration effect, that is, the migration of the sputtered particles that adhered to the base material 100 from the position to which they have initially adhered, can be inhibited and the inorganic oriented film 3A with arranged columnar crystals can be obtained more advantageously. Further, if necessary, cooling may be employed to obtain the temperature of the base material 100 within the aforementioned range when the inorganic oriented film 3A is formed.

The maximum magnetic flux density, B, in the direction parallel to the target surface S41 on the surface (target surface S41) of the target S4 with which plasma collides is preferably 1000 G or more.

In this case, plasma can be generated with good efficiency. As a result, the rate of forming the inorganic oriented film (film formation rate) can be increased without loosing the orientation ability of the inorganic oriented film obtained. By contrast if the maximum magnetic flux density B is less than the aforementioned lower limit value, a sufficient film formation rate sometimes cannot be obtained.

The distance (average value of the maximum value and minimum value) between the base material 100 and the target S4 is preferably 150 mm or more, more preferably 300 mm or more. In this case, spread of the irradiation angle of the sputtered particles can be decreased, and an inorganic oriented film with the columnar crystals arranged in an inclined state can be formed more advantageously. Furthermore, the inorganic oriented film that has been formed can be effectively prevented from damage by the generated plasma. By contrast, if the distance between the base material 100 and target S4 is too small, the inorganic oriented film that has been formed is sometimes damaged by the generated plasma. Furthermore, it is sometimes difficult to reduce the pressure of the atmosphere in the vicinity of the base material to the prescribed level. On the other hand, if the distance between the base material 100 and the target S4 is too large, a sufficient film formation rate sometimes cannot be obtained. Furthermore, it is sometimes difficult to provide for sufficient orientation of the inorganic oriented film obtained.

A material constituting the target S4 is appropriately selected according to the material for the formation of the inorganic oriented film 3A. For example, when an inorganic oriented film composed of SiO₂ is formed, the target S4 composed of SiO₂ is used, and when an inorganic oriented film composed of SiO is formed, the target S4 composed of SiO is used.

Further, in the present embodiment, the explanation was conducted by assuming that the magnets S31, S32 are permanent magnets, but they may be electromagnets.

The explanation provided hereinabove related to the formation of the inorganic oriented film 3A, but the inorganic oriented film 4A can be formed in the same manner.

A second embodiment of the liquid crystal panel in accordance with the present invention will be described below.

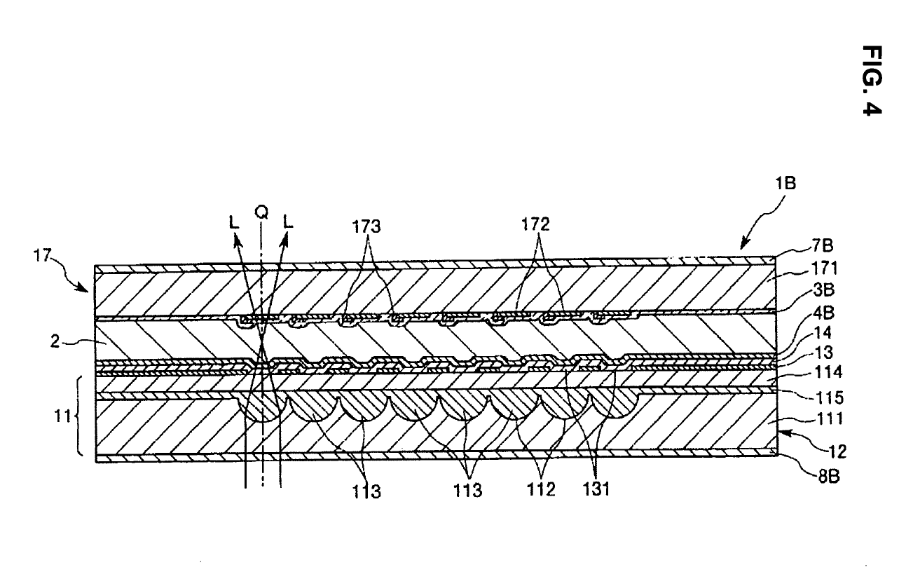

FIG. 4 is a schematic longitudinal cross-sectional view illustrating the second embodiment of the liquid crystal panel in accordance with the present invention. A liquid crystal panel 1B shown in FIG. 4 will be explained hereinbelow mainly with respect to the differences from the above-described first embodiment, and an explanation of features common to the two embodiments will be omitted.

As shown in FIG. 4, the liquid crystal panel (TFT liquid crystal panel) 1B comprises a TFT substrate (liquid crystal drive substrate) 17, an inorganic oriented film 3B joined to the TFT substrate 17, a facing substrate 12 for the liquid crystal panel, an inorganic oriented film 4B joined to the facing substrate 12 for the liquid crystal panel, a liquid crystal layer 2 composed of liquid crystals and sealed in the gap between the inorganic oriented film 3B and inorganic oriented film 4B, a polarizing film 7B joined to the outer surface side (surface on the opposite side from the surface facing the inorganic oriented film 4B) of the TFT substrate (liquid crystal drive substrate) 17, and a polarizing film 8B joined to the outer surface side (surface on the opposite side from the surface facing the inorganic oriented film 4B) of the facing substrate 12 for the liquid crystal panel. The inorganic oriented films 3B, 4B are formed by the same method (the method for forming an inorganic oriented film in accordance with the present invention) as the inorganic oriented films 3A, 4A described in the first embodiment hereinabove, and the polarizing films 7B, 8B are identical to the polarizing films 7A, 8A described in the first embodiment hereinabove.

The facing substrate 12 for the liquid crystal panel comprises a microlens substrate 11, a black matrix 13 provided on a surface layer 114 of the microlens substrate 11 and having openings 131 formed therein, and a transparent electrically conductive film (common electrode) 14 provided on the surface layer 114 so as to cover the black matrix 13.

The microlens substrate 11 comprises a substrate (first substrate) 111 with recesses for microlenses, which is provided with a plurality (a multiplicity) of recesses (recesses for microlenses) 112 each having a concave curved surface, and a surface layer (second substrate) 114 joined via a resin layer (adhesive layer) 115 to the surface of the substrate 111 where the recesses 112 are provided. In the resin layer 115, microlenses 113 are formed by a resin that fills the recesses 112.

The substrate 111 is produced from a flat starting material (transparent substrate), and a plurality (a multiplicity) of recesses 112 are formed in the surface thereof The recesses 112 can be formed, for example by a dry etching method or a wet etching method by using a mask.

The substrate 111 is formed, for example, from a glass or the like.

It is preferred that the thermal expansion coefficient of the aforementioned starting material be substantially equal to the thermal expansion coefficient of the glass substrate 171 (for example, the ratio of the two thermal expansion coefficients is about 1/10 to 10). In this case, in the liquid crystal panel obtained, warping, deflection, and peeling that may be caused by the difference between the two thermal expansion coefficients when the temperature changes can be prevented.

From this standpoint, it is preferred that the substrate 111 and the glass substrate 171 be composed of the same material. In this case, in the liquid crystal panel obtained, warping, deflection, and peeling that may be caused by the difference between the two thermal expansion coefficients when the temperature changes can be effectively prevented.

In particular, when the microlens substrate 11 is used in a TFT liquid crystal panel of high-temperature polysilicon, it is preferred that the substrate 111 with recesses for microlenses be composed of quartz glass. A TFT liquid crystal panel comprises a TFT substrate as a liquid crystal drive substrate. A quarts glass whose properties minimally change under the effect of the environment in the manufacturing process is preferably used for such TFT substrates. Therefore, if the substrate 111 is accordingly also composed of quartz glass, then a TFT liquid crystal panel with excellent stability characterized by high resistance to warping and deflection can be obtained.

A resin layer (adhesive layer) 115 for covering the recesses 112 is provided on the upper surface of the substrate 111.

The microlenses 113 are formed by filling the inside of the recesses 112 with the material constituting the resin layer 115.

The resin layer 115 can be composed, for example, of a resin (adhesive) with a refractive index higher than the refractive index of the material constituting the substrate 111 and can be advantageously composed, for example, of an UV-curable resin such as acrylic resin, epoxy resin, and acryl-epoxy resin.

A flat surface layer 114 is provided on the upper surface of the resin layer 115.

The surface layer (glass layer) 114 can be composed, for example, of glass. In this case, it is preferred that the thermal expansion coefficient of the surface layer 114 be substantially equal (for example, the ratio of the two thermal expansion coefficients is about 1/10 to 10) to the thermal expansion coefficient of the substrate 111. In this way, warping, deflection, or peeling that may be caused by the difference in thermal expansion coefficient between the substrate 111 and the surface layer 114 can be prevented. This effect can be obtained to an even greater extent if the substrate 111 and the surface layer 114 are composed of the same material.

From the standpoint of obtaining required optical properties when the microlens substrate 11 is used for a liquid crystal panel, the thickness of the surface layer 114 is usually selected at about 5-1000 μm, more preferably about 10-150 μm.

The surface layer (barrier layer) 114 can be also composed, for example, of a ceramic. Examples of suitable ceramics include nitride ceramics such as AlN, SiN, TiN, and BN, oxide ceramics such as Al₂O₃ and TiO₂, and carbide ceramics such as WC, TiC, ZrC, and TaC. When the surface layer 114 is composed of a ceramic, no specific limitation is placed on the thickness of the surface layer 114, but this thickness is preferably about 20 nm to 20 μm, more preferably about 40 nm to 1 μm.

If necessary, the surface layer 114 can be omitted.

The black matrix 13 has a light-shielding function and is composed, for example, of a metal such as Cr, Al, Al alloy, Ni, Zn, and Ti, or a resin having carbon or titanium dispersed therein.

The transparent electrically conductive film 14 has electric conductivity and is composed, for example, of indium tin oxide (ITO), indium oxide (IO), or tin oxide (SnO₂).

The TFT substrate 17 is a substrate for driving liquid crystals of the liquid crystal layer 2 and comprises a glass substrate 171, a plurality (a multiplicity) of pixel electrodes 172 provided on the glass of 171 and arranged in the form of a matrix (row-column configuration), and a plurality (a multiplicity) of thin-film transistors (TFT) 173 corresponding to the pixel electrodes. The description of sealing materials, wiring, and the like with reference to FIG. 4 is omitted.

For the reasons described hereinabove, the glass substrate 171 is preferably composed of quartz glass.

The pixel electrodes 172 drive liquid crystals of the liquid crystal layer 2 by charging and discharging the transparent electrically conductive film (common electrode) 14. The pixel electrodes 172 are composed, for example, of a material identical to that of the aforementioned transparent eclectically conductive film 14.

The thin-film transistors 173 are connected to corresponding adjacent pixel electrodes 172. Furthermore, the thin-film transistors 173 are connected to the control circuits (not shown in the figure) to control the electric current supplied to the pixel electrodes 172. Charging and discharging of the pixel electrodes 172 is thereby controlled.

The inorganic oriented film 3B is joined to the pixel electrodes 172 of the TFT substrate 17, and the inorganic oriented film 4B is joined to the transparent electrically conductive film 14 of the facing substrate 12 for a liquid crystal panel.

The liquid crystal layer 2 comprises liquid crystal molecules and the orientation of those liquid crystal molecules, that is, the orientation of the liquid crystal, changes correspondingly to charging and discharging of the pixel electrodes 172.

In such a liquid crystal panel 1B, one microlens 113, one opening 131 of the black matrix 13 corresponding to the optical axis Q of the microlens 113, one pixel electrode 172, and one thin-film transistor 173 connected to the pixel electrode 172 usually correspond to one pixel.

An incident light L traveling from the facing substrate 12 for a liquid crystal panel passes through the substrate 111 and is transmitted via the resin layer 115, surface layer 114, opening 131 of the black matrix 13, transparent electrically conductive film 14, liquid crystal layer 2, pixel electrode 172, and glass substrate 171, while being converged as it passes through the microlens 113. At this time, because the polarizing film 8B is provided on the light incidence side of the microlens substrate 11, when the incident light L passes through the liquid crystal layer 2, the incident light L becomes a linearly polarized light. In this process, the polarization direction of the incident light L is controlled correspondingly to the orientation state of liquid crystal molecules of the liquid crystal layer 2. Therefore, the luminosity of the outgoing light can be controlled by causing the incident light L that passed through the liquid crystal panel 1B to pass through the polarizing film 7B.

Thus, the liquid crystal panel 1B comprises the microlenses 113 and the incident light L that passed through microlenses 113 is converged and passes through the openings 131 of the black matrix 13. On the other hand, in the portion where the openings 131 of the black matrix 13 have not been formed, the incident light L is shielded. Therefore, in the liquid crystal panel 1B, leakage of the unnecessary light from the portions other than pixels is prevented and the attenuation of the incident light L in the pixel portions is inhibited. As a result, the liquid crystal panel 1B has a high light transmittance in pixel portions.

The liquid crystal panel 1B can be manufactured, for example, by forming the inorganic oriented films 3B, 4B respectively on the TFT substrate 17 and facing substrate 12 for a liquid crystal panel that were manufactured by the well-known method, then joining the two via a sealing material (not shown in the figures), injecting liquid crystals into a gap formed therebetween from a sealing hole (not shown in the figure) of the gap, and closing the sealing hole.

In the above-described liquid crystal panel 1B, a TFT substrate was used as a liquid crystal drive substrate, but other liquid crystal drive substrates different from the TFT substrates, for example, TFD substrate and STN substrate, may be also used as the liquid crystal drive substrate.

The liquid crystal panel thus provided with the above-described inorganic oriented films can be advantageously used for devices with an intensive light source or devices used outdoors.

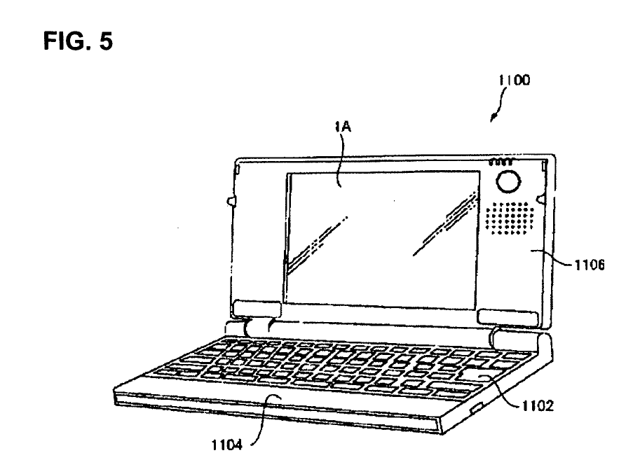

An electronic device (liquid-crystal display device) in accordance with the present invention, which comprises the above-described liquid crystal panel 1A, will be described hereinbelow in greater detail based on the embodiment illustrated by FIGS. 5 to 7.

FIG. 5 is a perspective view illustrating the configuration of a personal computer of a mobile (or notebook) type which employs the electronic device in accordance with the present invention.

Referring to this figure, a personal computer 1100 is composed of a main body 1104 equipped with a keyboard 1102 and a display unit 1106, wherein the display unit 1106 is rotatably supported by the main body 1104 via a hinge structure.

In such personal computer 1100, the display unit 1106 comprises the above-described liquid crystal panel 1A and a backlight (not shown in the figure). The light from the backlight is transmitted through the liquid crystal panel 1A, thereby allowing an image (information) to be displayed.

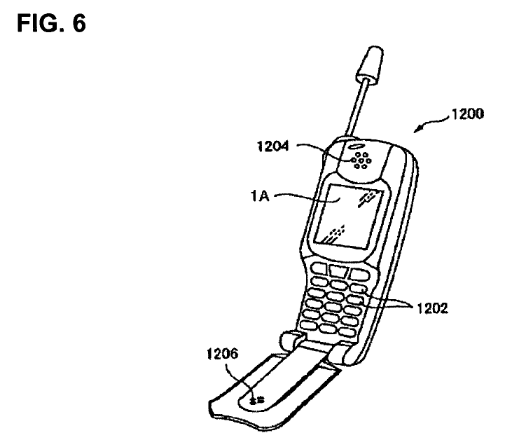

FIG. 6 is a perspective view illustrating the configuration of a cellular phone (including a PHS) type which employs the electronic device in accordance with the present invention.

Referring to this figure, a cellular phone 1200 comprises a plurality of operation buttons 1202, a voice receiving orifice 1204, a voice transmitting orifice 1206, the above-described liquid crystal panel 1A, and a backlight (not shown in the figure).

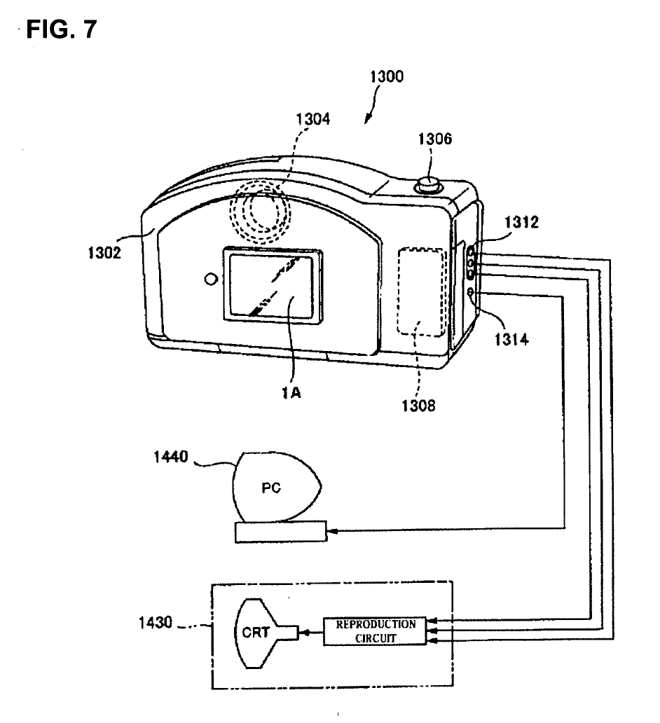

FIG. 7 is a perspective view illustrating the configuration of a digital still camera which employs the electronic device in accordance with the present invention. Connection to the external device is also shown in the figure in a simple manner.

By contrast with the usual camera in which a silver halide photographic film is photosensitized by the optical image of an object, in a digital still camera 1300 the optical image of the object is photoelectrically converted into pickup signals (image signals) by a pickup element such as a CCD (Charge Coupled Device).

The above-described liquid crystal panel 1A and a backlight (not shown in the figure) are provided at the rear surface of the case (body) 1302 of the digital still camera 1300, and display is carried out based on the pickup signals produced by the CCD. The liquid crystal panel 1A functions as a finder for displaying the object as an electronic image.

A circuit substrate 1308 is disposed inside the case. A memory capable of storing (memorizing) imaging signals is disposed at the circuit substrate 1308.

Further, a light-receiving unit 1304 comprising an optical lens (imaging optical system) or CCD is provided on the front surface side (back surface side in the configuration shown in the figure) of the case 1302.

If a photographer recognizes the object displayed on the liquid crystal panel 1A and pushes down the shutter button 1306, the pickup signal of the CCD at this point in time is transferred to and stored in the memory of the circuit substrate 1308.

Further, in the digital still camera 1300, a video signal output terminal 1312 and an input/output terminal 1314 for data communication are provided at the side surface of the case 1302.

Further, as shown in the figure, if necessary, a television monitor 1430 is connected to the video signal output terminal 1312, and a personal computer 1440 is connected to the input/output terminal 1314 for data communication. Furthermore, by the prescribed operations, the imaging signal stored in the memory of the circuit substrate 1308 is outputted to the television monitor 1430 and personal computer 1440.

An electronic device (liquid-crystal projector) using the above-described liquid crystal panel 1B will be described hereinbelow as an example of the electronic device in accordance with the present invention.

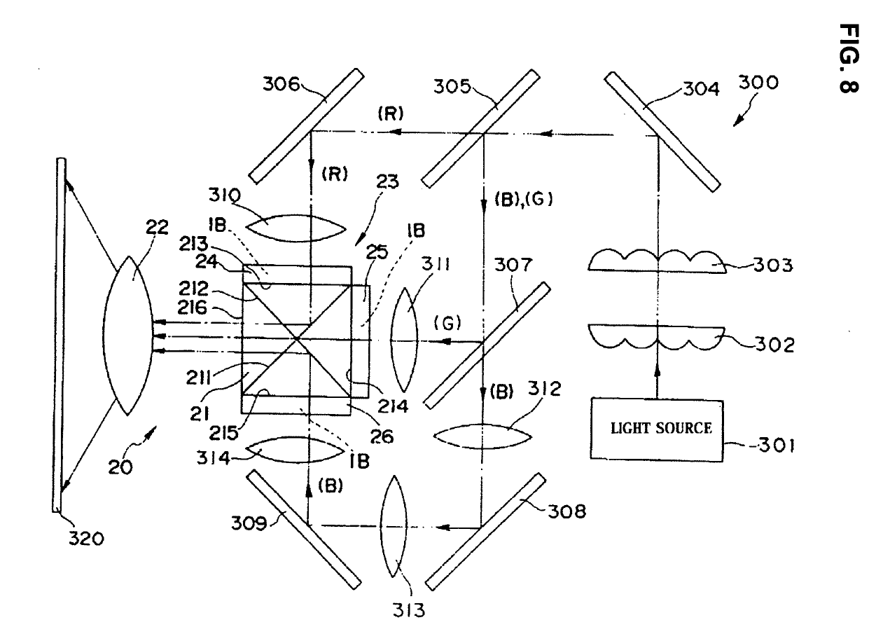

FIG. 8 shows schematically the optical system of the electronic device (projection display device) in accordance with the present invention.

As shown in the figure, a projection display device 300 comprises a light source 301, an illumination optical system comprising a plurality of integrator lenses, a color separation optical system (light guide optical system) comprising a plurality of dichroic mirrors and the like, a liquid crystal light valve (liquid crystal light shutter array) 24 (for red color) corresponding to red color, a liquid crystal light valve (liquid crystal light shutter array) 25 (for green color) corresponding to green color, a liquid crystal light valve (liquid crystal light shutter array) 26 (for blue color) corresponding to blue color, a dichroic prism (color synthesizing optical system) 21 having formed thereon a dichroic mirror surface 211 reflecting only red light and a dichroic mirror surface 212 reflecting only blue light, and a projection lens (projection optical system) 22.

Further, the illumination optical system comprises integrator lenses 302 and 303. The color separation optical system comprises mirrors 304, 306, 309 a dichroic mirror 305 reflecting blue light and green light (transmitting only red light), a dichroic mirror 307 reflecting only green light, a dichroic mirror 308 reflecting only blue light (or mirror reflecting blue light), and converging lenses 310, 311, 312, 313, and 314.

The liquid crystal light valve 25 comprises the above-described liquid crystal panel 1B. The liquid crystal light valves 24 and 26 have a configuration similar to that of the liquid crystal light valve 25, and the liquid crystal panels 1B comprised in those liquid crystal light valves 24, 25, and 26 are connected to respective drive circuits (not shown in the figures).

Further, in the projection display device 300, the optical block 20 is composed of a dichroic prism 21 and projection lens 22. Further, the display unit 23 is composed of the optical block 20 and the liquid crystal light valves 24, 25, and 26 disposed fixedly with respect to the dichroic prism 21.

The operation of the projection display device 300 will be explained hereinbelow.

White light (white luminous flux) emitted from the light source 301 is transmitted via the integrator lenses 302 and 303. The light intensity (luminosity distribution) of the white light is made uniform by the integrator lenses 302 and 303. It is preferred that the intensity of the white light emitted from the light source 301 be comparatively high. As a result, brighter image can be formed on a screen 320. Furthermore, because the liquid crystal panel 1B with excellent light resistance is used in the projection display device 300, excellent long-term stability can be obtained even when the intensity of light emitted from the light source 301 is high.

The white light that was transmitted through the integrator lenses 302 and 303 is reflected by the mirror 304 to the left, as shown in FIG. 8, and blue light (B) and green light (G) of this reflected light are reflected down, as shown in FIG. 8, by respective dichroic mirrors 305. The red light (R) is transmitted through the dichroic mirror 305.

The red light that was transmitted through the dichroic mirror 305 is reflected down, as shown in FIG. 8, by the mirror 306, and this reflected light is shaped by the converging lens 310 and falls on the liquid crystal light valve 24 for red color.

The green light of the blue light and green light, which were reflected by the dichroic mirror 305, is reflected to the left, as shown in FIG. 8, by the dichroic mirror 307, and the blue light is transmitted through the dichroic mirror 307.

The green light reflected by the dichroic mirror 307 is shaped by the converging lens 311 and falls on the liquid crystal light valve 25 for green color.

Further, the blue light that was transmitted through the dichroic mirror 307 is reflected to the left, as shown in FIG. 8, by the dichroic mirror (or mirror) 308, and this reflected light is reflected up, as shown in FIG. 8, by the mirror 309. The blue light is shaped by the converging lenses 312, 313, and 314 and falls on the liquid crystal light valve 26 for blue color.

Thus, the white light emitted from the light source 301 is color separated into three primary colors (red, green, and blue) by the color separation optical system and guided to fall on the respective liquid crystal light valves.

At this time, each pixel (thin-film transistor 173 and pixel electrode 172 connected thereto) of the liquid crystal panel 1B of the liquid crystal light valve 24 is switching controlled (ON/OFF), that is, modulated, by a drive circuit (drive means) actuated based on the image signal for red color.

Similarly, the green color and blue color fall on the liquid crystal light valve 25 and liquid crystal light valve 26, respectively, and are modulated by respective liquid crystal panels 1B. As a result, an image for green color and an image for blue color are formed. At this time, each pixel of the liquid crystal panel 1B of the liquid crystal light valve 25 is switching controlled by the drive circuit actuated based on the image signal for green color, and each pixel of the liquid crystal panel 1B of the liquid crystal light valve 26 is switching controlled by the drive circuit actuated based on the image signal for blue color.

In this case, the red light, green light, and blue light are modulated by liquid crystal light valves 24, 25, and 26, respectively, thereby forming an image for red light, an image for green light, and an image for blue light, respectively.

The image for red light formed by the liquid crystal light valve 24, that is, the red light from the liquid crystal light valve 24, falls from the surface 213 on the dichroic prism 21, is reflected to the left, as shown in FIG. 8, by the dichroic mirror surface 211 and transmitted through the dichroic mirror surface 212, and outgoes from the outgoing surface 216.

Further, the image for green light formed by the liquid crystal light valve 25, that is, the green light from the liquid crystal light valve 25, falls from the surface 214 on the dichroic prism 21, is transmitted through the dichroic mirror surfaces 211 and 212, and outgoes from the outgoing surface 216.

Further, the image for blue light formed by the liquid crystal light valve 26, that is, the blue light from the liquid crystal light valve 26, falls from the surface 215 on the dichroic prism 21, is reflected to the left, as shown in FIG. 8, by the dichroic mirror surface 212 and transmitted through the dichroic mirror surface 211, and outgoes from the outgoing surface 216.

The images formed by lights of each color from the liquid crystal light valves 24, 25, and 26, that is, by the liquid crystal light valves 24, 25, and 26, are synthesized by the dichroic prism 21 and a color image is thus formed. This image is projected (enlarged projection) by the projection lens 22 on the screen 320 disposed in the prescribed location.

In addition to the personal computer (mobile personal computer) shown in FIG. 5, cellular phone shown in FIG. 6, digital still camera shown in FIG. 7, and the projection display device shown in FIG. 8, the examples of the electronic devices in accordance with the present invention include television sets, video cameras, viewfinders, video tape recorders of a direct viewing monitor type, vehicle navigation devices, pagers, electronic notebooks (including those provided with communication functions), electronic dictionaries, electronic calculators, electronic game devices, word processors, workstations, TV phones, television monitors for crime prevention, electronic binoculars, POS terminals, devices equipped with touch panels (for example, cash dispensers of financial institutions, automatic machines for selling tickets), medical equipment (for example, electronic body thermometers, blood pressure meters, blood sugar meters, electrocardiograph display devices, ultrasonic diagnostic devices, display devices for endoscopy), fish finders, various measurement devices, instruments (for example, instruments for vehicles, aircrafts, and ships), and flight simulators. It goes without saying that the above-described liquid crystal panel in accordance with the present invention can be used as a display unit and monitor unit of those electronic devices.

The above-described inorganic oriented film, substrate for an electronic device, liquid crystal panel, electronic device, and method for forming an inorganic oriented film in accordance with the present invention were described based on the embodiments thereof illustrated by the appended drawings, but the present invention is not limited thereto.

For example, the method for forming an inorganic oriented film in accordance with the present invention may additionally include one or several steps implemented with any object. Further, for example, in the substrate for an electronic device, liquid crystal panel, and electronic device in accordance with the present invention, the configuration of each component can be replaced with any configuration demonstrating identical functions, or any additional configuration may be employed.

Further, in the above-described embodiment, the explanation was conducted with respect to a projection display device (electronic device) having three liquid crystal panels, wherein the liquid crystal panel in accordance with the present invention was employed for all those liquid crystal panels. However, the liquid crystal panel in accordance with the present invention may be used in at least one of them. In this case, the present invention is preferably employed in the liquid crystal panel used in the liquid crystal light valve for blue color.

### EXAMPLES

Manufacture of Liquid Crystal Panel

The liquid crystal panel shown in FIG. 4 was manufactured in the following manner.

### Working Example 1

First, a microlens substrate was manufactured in the following manner.

A non-processed quartz glass substrate (transparent substrate) with a thickness of about 1.2 mm was prepared as a starting material. It was immersed in a cleaning solution (liquid mixture of sulfuric acid and aqueous hydrogen peroxide) at a temperature of 85° C. and the surface thereof was cleaned.

Polycrystalline silicon films with a thickness of 0.4 μm were thereafter formed on the front and rear surfaces of the quartz glass substrate by a CVD method.

Openings corresponding to the recesses that will be formed were then formed in the polycrystalline silicon films thus formed.

This was done in the following manner. First, a resist layer having a pattern of recesses that will be formed was formed on the polycrystalline silicon films. Then, dry etching with CF gas was carried out with respect to the polycrystalline silicon films and openings were formed. The resistance layer was then removed.

Recesses were then formed on the quartz glass substrate by immersing the quartz glass substrate for 120 min into an etching solution (mixed aqueous solution containing 10 wt. % hydrofluoric acid+10 wt. % glycerin) and wet etching (etching temperature 30° C.) was conducted.

A substrate with recesses for microlenses was then obtained by immersing the quartz glass substrate for 5 min into a 15 wt. % aqueous solution of tetramethyl ammonium hydroxide and removing the polycrystalline silicon films formed on the front and rear surfaces.

The surface of this substrate with recesses for microlenses where the recesses were formed was bubble-free coated with an ultraviolet (UV)-curable acrylic optical adhesive (refractive index 1.60), then a cover glass (surface layer) made from quartz glass was joined to the aforementioned optical adhesive, and a laminated body was then obtained by illuminating the optical adhesive with UV rays and curing the optical adhesive.

A microlens substrate was then obtained by grinding and polishing the cover glass to a thickness of 50 μm.

The thickness of the resin layer in the microlens substrate thus obtained was 12 μm.

A light shielding film (Cr film) with a thickness of 0.16 μm that was provided with openings in the locations corresponding to microlenses of the cover glass, that is, a black matrix, was then formed by using sputtering and photolithography on the microlens substrate obtained in the above-described manner. An ITO film (transparent electrically conductive film) with a thickness of 0.15 μm was then formed by sputtering on the black matrix and a facing substrate for a liquid crystal panel was manufactured.

An inorganic oriented film was then formed in the below-described manner by using the device shown in FIG. 3 on the transparent electrically conductive film of the facing substrate for an liquid crystal panel that was thus obtained.

First, the facing substrate for a liquid crystal panel (base material) was disposed on the base material holder S6 located in the vacuum chamber S1. The distance between the target S4 and the facing substrate for a liquid crystal panel was 550 μm.

The pressure of the atmosphere in the vicinity of the facing substrate for a liquid crystal panel was then reduced with the evacuation pump S5 to 5.0×10⁻⁴ Pa.

Argon gas was then supplied with the gas supply source S2 into the vacuum chamber S1, a high-frequency (13.56 MHz) power of 500 W was applied to the electrode S3 and plasma was generated and caused to collide with the target S4. SiO₂ was used as the target S4.

The target S4 with which plasma has collided emitted sputtered particles toward the facing substrate for a liquid crystal panel and an inorganic oriented film composed of SiO₂ and having an average thickness of 0.05 μm was formed on the transparent electrically conductive film. The irradiation angle, θs, of the sputtered particles was 80°. The facing substrate for a liquid crystal panel was not heated during film formation. Further, the maximum magnetic flux density in the direction parallel to the target surface S41 on the target surface S41 was 1500 G.

Further, the columnar crystal constituting the inorganic oriented film that was thus formed had an inclination angle, θc, with respect to the facing substrate for a liquid crystal panel of 45° and the width thereof was 20 nm.

An inorganic oriented film was also formed in the same manner as described above on the surface of a TFT substrate (made from quartz glass) that was prepared separately.

The facing substrate for a liquid crystal panel, which had the inorganic oriented film formed thereon, and the TFT substrate, which had the inorganic oriented film formed thereon, were joined via a sealing material. This joining was so conducted that the orientation direction of the inorganic oriented films was shifted by 90° so that the liquid crystal molecules constituting the liquid crystal layer were twisted to the left.

Then, liquid crystals (manufactured by Merck Co., MJ99247) were introduced through a sealing hole into the gap formed between the inorganic oriented film—inorganic oriented film, and this sealing hole was then closed. The thickness of the obtained liquid crystal layer was about 3 μm.

A TFT liquid crystal panel with the structure shown in FIG. 4 was then manufactured by joining the polarizing film 8B and polarizing film 7B to the outer surface side of the facing substrate for a liquid crystal panel and the outer surface side of the TFT substrate, respectively. Films composed of polyvinyl alcohol (PVA) and subjected to uniaxial stretching were used as the polarizing films. The joining direction of the polarizing film 7B and polarizing film 8B was determined based on the orientation direction of the inorganic oriented film 3B and inorganic oriented film 4B. Thus, the polarizing film 7B and polarizing film 8B were so joined that the incident light was not transmitted when voltage was applied and the incident light was transmitted when no voltage was applied.

The pretilt angle of the manufactured liquid crystal panel was within a range of 3-7°.

### Comparative Example 1

A liquid crystal panel was manufactured in the same manner as in the above-described Working Example 1, except that the apparatus shown in FIG. 3 was not used, a solution (manufactured by Japan Synthetic Rubber Co., Ltd.) of a polyimide resin (PI) was prepared, a film with an average thickness of 0.05 μm was formed on the transparent electrically conductive film of the facing substrate of a liquid crystal panel, and an oriented film was obtained by conducting rubbing so that the pretilt angle became 2-3°. Further, in Comparative Example 1, dust was generated during rubbing.

### Comparative Example 2

A liquid crystal panel was manufactured in the same manner as in the above-described Working Example 1, except that the facing substrate for a liquid crystal panel was irradiated, without the inclination, with the sputtered particles generated from the target S4.

### Comparative Example 3

An liquid crystal panel was manufactured in the same manner as in the above-described Working Example 1, except that an inorganic oriented film was formed by using a vapor deposition apparatus (manufactured by Shin Meiwa Kogyo K. K.; trade name VDC-1300) under the following conditions: the pressure of the atmosphere was 2×10⁻² Pa and the distance between the target and the base material was 1000 mm.

Evaluation of Liquid Crystal Panels

Optical transmittance of the liquid crystal panels manufactured in the above-described working example and comparative examples was continuously measured. Measurements of the optical transmittance were conducted by holding the liquid crystal panels at a temperature of 50° C. and illuminating with white light with a luminous flux density of 15 lm/mm² in a state without voltage application.

The liquid crystal panels were evaluated by the following four levels, where the interval (light resistance interval) required for the optical transmittance of the liquid crystal panel manufactured in Comparative Example 1 to decrease to 50% of the initial optical transmittance, this time being measured from the start of illumination, was selected as a reference.

⊙: Light resistance interval is not less than 5 times longer than that of Comparative Example 1.

◯: Light resistance interval is not less than 2 times and less than 5 times longer than that of Comparative Example 1.

Δ: Light resistance interval is not less than 1 time and less than 2 times longer than that of Comparative Example 1.

X: Light resistance interval is shorter than that of Comparative Example 1.

The results obtained in evaluating the liquid crystal panels are presented in Table 1 together with the inorganic oriented film formation conditions, average thickness of the inorganic oriented film, width and inclination angle, θc, of columnar crystals, and pretilt angle of the liquid crystal panels.

TABLE 1

| | | | | | | Distance | | | | | |
|---|---|---|---|---|---|---|---|---|---|---|---|
| | | Pressure of | Irradiation | High | | between | Average | | Inclination | | |
| | Material | atmosphere | angle of | frequency | Maximum | base | thickness | Width of | angle of | | |
| | constituting | close to | sputtered | applied to | magnetic | material | of oriented | columnar | columnar | Pretilt | |
| | the oriented | base material | particles, | electrode | flux density | and target | film | crystals | crystals, | angle | Light |
| | film | [Pa] | θs [°] | [MHz] | [G] | [mm] | [μm] | [nm] | θc [°] | [°] | resistance |
| Working | SiO₂ | 5 × 10⁻⁴ | 80 | 13.56 | 1500 | 550 | 0.05 | 20 | 45 | 3-7 | ⊙ |
| Example | | | | | | | | | | | |
| Comparative | PI | — | — | — | — | — | 0.05 | — | — | 2-3 | — |
| Example 1 | | | | | | | | | | | |
| Comparative | SiO₂ | 5 × 10⁻⁴ | 0 | 13.56 | 1500 | 550 | 0.05 | 20 | 90 | 0 | ⊙ |
| Example 2 | | | | | | | | | | | |
| Comparative | SiO₂ | 2 × 10⁻² | — | — | — | 1000 | 0.05 | 0 | — | 0 | ◯ |
| Example 3 | | | | | | | | | | | |

Table 1 clearly shows that in the liquid crystal panel in accordance with the present invention, light resistance was superior to that of the liquid crystal panel of Comparative Example 1.

Furthermore, in the liquid crystal panel in accordance with the present invention, a sufficient pretilt angle was obtained and the orientation state of liquid crystal molecules could be reliably controlled, but in the liquid crystal panels of Comparative Examples 2 and 3, a sufficient pretilt angle was not obtained and the orientation state of liquid crystal molecules was difficult to control.

Evaluation of Liquid Crystal Projector (Electronic Device)

Liquid-crystal projectors (electronic devices) with the structure shown in FIG. 8 were assembled by using TFT liquid crystal panels manufactured in the working example and comparative examples and then was continuously driven for 5000 h.

The results showed that with the liquid-crystal projector (electronic device) manufactured by using the liquid crystal panel of the working example, bright projected images were produced even after continuous operation for a long time.

By contrast, in the liquid-crystal projector manufactured by using the liquid crystal panel of Comparative Example 1, luminosity of the projected image clearly decreased with the drive time. This was apparently because at the initial stage the orientation of liquid crystal molecules was ordered, but in long-term operation the oriented film deteriorated and orientation ability of liquid crystal molecules was degraded. In the liquid-crystal projectors manufactured by using the liquid crystal panels of Comparative Examples 2 and 3, bright projected images were not obtained from the beginning of operation. This was apparently because the original orientation ability of the inorganic oriented films was poor.

Further, when a personal computer, a cellular phone, and a digital still camera comprising the liquid crystal panel in accordance with the present invention were fabricated and evaluated in a similar manner, similar results were obtained.

Those results demonstrate that the liquid crystal panel and electronic device in accordance with the present invention have excellent light resistance and allow stable characteristics to be obtained even in long-term use.

1. A method for forming an inorganic oriented film on a base material, comprising:
reducing a pressure of an atmosphere near said base material to about 5.0×10⁻² Pa or below, causing plasma to collide with a target provided opposite said base material, and drawing out sputtered particles;
irradiating said base material with said sputtered particles from a direction inclined at a prescribed angle, θs, with respect to a direction perpendicular to a surface of said base material where said inorganic oriented film will be formed; and
forming an inorganic oriented film composed substantially of an inorganic material on said base material.

2. The method for forming an inorganic oriented film according to claim 1, wherein said prescribed angle θs is at least about 60°.

3. The method for forming an inorganic oriented film according to claim 1, wherein a distance between said base material and said target is at least about 150 mm.

4. The method for forming an inorganic oriented film according to claim 1, wherein when said inorganic oriented film is formed, a maximum magnetic flux density on a surface of said target with which said plasma collides, in a direction parallel to said surface of the target, is at least about 1000 G.

5. The method for forming an inorganic oriented film according to claim 1, wherein said inorganic material is capable of columnar crystallization.

6. The method for forming an inorganic oriented film according to claim 1, wherein said inorganic material substantially comprises an oxide of silicon.

7. An inorganic oriented film formed by the method for forming an inorganic oriented film according to claim 1.

8. The inorganic oriented film according to claim 7, wherein columnar crystals are inclined at the prescribed angle relative to the base material.

9. The inorganic oriented film according to claim 7, wherein an average thickness of the inorganic oriented film is about 0.02-0.3 μm.

10. A substrate for an electronic device, comprising:
electrodes on a substrate; and
the inorganic oriented film according to claim 7 on the substrate.

11. A liquid crystal panel comprising the inorganic oriented film according to claim 7 and a liquid crystal layer.

12. A liquid crystal panel comprising:
a pair of the inorganic oriented films according to claim 7; and
a liquid crystal layer between said pair of the inorganic oriented films.

13. An electronic device comprising the liquid crystal panel of claim 11.

14. An electronic device comprising a light valve including the liquid crystal panel described in claim 11, wherein an image is projected by using said light valve.

15. An electronic device comprising:
three light valves corresponding to red color, green color, and blue color for forming images;
a light source;
a color separation optical system separating the light from said light source into red, green, and blue lights, and guiding each said light into the corresponding light valve;
a color synthesizing optical system synthesizing each said image; and
a projecting optical system projecting said synthesized image, wherein
said light valves comprise the liquid crystal panel described in claim 11.
